(19) United States
(12) Patent Application Publication
(10) Pub. No.: US 2011/0043573 A1
(43) Pub. Date: Feb. 24, 2011

(54) PIEZOELECTRIC ACTUATOR, METHOD FOR MANUFACTURING PIEZOELECTRIC ACTUATOR, LIQUID-EJECTING HEAD, AND LIQUID-EJECTING APPARATUS

(75) Inventor: Katsumi UMEDA, Fujimi-machi (JP)

Correspondence Address: WORKMAN NYDEGGER;1000 Eagle Gate Tower, 60 East South Temple, Salt Lake City, UT, 84111, US

(73) Assignee: SEIKO EPSON CORPORATION, Tokyo (JP)

(21) Appl. No.: 12/858,309

(22) Filed: Aug. 17, 2010

(30) Foreign Application Priority Data
Aug. 18, 2009 (JP) 2009-188942

(51) Int. Cl. B41J 2/045; H01L 41/053; H01L 41/22

(52) U.S. Cl. 347/68; 310/340; 29/25.35

(57) ABSTRACT

A piezoelectric actuator includes a substrate; a diaphragm overlying the substrate; a lower electrode overlying the diaphragm; a piezoelectric body overlying the lower electrode; an upper electrode that includes a first upper sub-electrode which overlies the piezoelectric body and which has a first sputtering rate and also includes a second upper sub-electrode which overlies the first upper sub-electrode, which has a second sputtering rate less than the first sputtering rate, and which is the uppermost layer; and a protective film extending over side surfaces of the piezoelectric body and the second upper sub-electrode, a portion of the protective film that overlies the second upper sub-electrode being removed by sputtering.

This application claims a priority to Japanese Patent Application No. 2009-188942 filed on Aug. 18, 2009 which is hereby expressly incorporated by reference herein in its entirety.

### BACKGROUND

1. Technical Field

The present invention relates to a piezoelectric actuator, a method for manufacturing the piezoelectric actuator, a liquid-ejecting head including the piezoelectric actuator, and a liquid-ejecting apparatus including the liquid-ejecting head.

2. Related Art

Piezoelectric bodies including crystals of lead zirconate titanate (PZT) have spontaneous polarization, a high dielectric constant, electro-optic effects, piezoelectricity, and pyroelectricity and therefore are applied to various devices such as piezoelectric elements. The piezoelectric elements each include a pair of electrodes and are deformed by applying a voltage between the electrodes.

Piezoelectric actuators make use of the fact that piezoelectric elements are deformed by the application of voltage. The piezoelectric actuators include members, such as diaphragms, deformed by the piezoelectric elements.

Liquid-ejecting heads each include a plurality of pressure-generating chambers communicating with nozzle openings for ejecting liquids. Piezoelectric actuators form portions of the pressure-generating chambers. The deformation of the piezoelectric actuators causes changes in volume of the pressure-generating chambers. When the pressure-generating chambers are filled with liquids, the reduction in volume of the pressure-generating chambers increases the pressure in the pressure-generating chambers, thereby ejecting the liquids through the nozzle openings. A liquid-ejecting apparatus includes such a liquid-ejecting head. A method for manufacturing the liquid-ejecting head is as follows: liquid-ejecting head components including piezoelectric elements and piezoelectric actuators are formed on a wafer and are then divided such that liquid-ejecting heads are obtained.

Electrodes of a piezoelectric element and an insulating protective film for protecting the piezoelectric element from moisture inhibit the deformation of a piezoelectric body to significantly influence vibrational properties of a piezoelectric actuator. The influence thereof depends on the Young's modulus and thickness of each of the electrodes and the insulating protective film. For example, JP-A-2007-276384 (pp. 11-12, FIG. 9) discloses an ink jet head which serves as a liquid-ejecting head and which is prepared in such a manner that an insulating protective film is formed on a piezoelectric element and portions of the insulating protective film that correspond to electrodes of the piezoelectric element are partly etched off such that the insulating protective film is prevented from inhibiting the deformation of the piezoelectric element.

The thickness and etching rate of an insulating protective film vary depending on portions of a wafer. Therefore, it is difficult to stop etching at the boundary between the insulating protective film and an electrode of each piezoelectric element; hence, the electrode is etched and the thickness of the electrode varies depending on portions of the wafer. This varies the influence of the electrode on the deformation of the piezoelectric element. Therefore, liquid-ejecting heads or piezoelectric actuators included in the liquid-ejecting heads are different in vibrational properties from each other and the amount of a liquid ejected therefore varies.

The term “etching” as used herein covers sputtering.

### SUMMARY

An advantage of some aspects of the present invention is that at least one of the above problems is solved.

A first aspect of the present invention provides a piezoelectric actuator. The piezoelectric actuator includes a substrate; a diaphragm overlying the substrate; a lower electrode overlying the diaphragm; a piezoelectric body overlying the lower electrode; an upper electrode that includes a first upper sub-electrode which overlies the piezoelectric body and which has a first sputtering rate and also includes a second upper sub-electrode which overlies the first upper sub-electrode, which has a second sputtering rate less than the first sputtering rate, and which is the uppermost layer; and a protective film extending over side surfaces of the piezoelectric body and the second upper sub-electrode, a portion of the protective film that overlies the second upper sub-electrode being removed by sputtering.

In the piezoelectric actuator, the second sputtering rate of the second upper sub-electrode is less than the first sputtering rate of the first upper sub-electrode; hence, the second upper sub-electrode is more resistant to sputtering when the portion of the protective film that is disposed on the second upper sub-electrode is removed by sputtering as compared to the case where the upper electrode includes the first upper sub-electrode only and therefore a difference in thickness of the second upper sub-electrodes can be reduced. Therefore, the inhibitory effect of the upper electrode on the deformation of the piezoelectric body can be reduced. This allows the piezoelectric actuator to have small differences in vibrational properties.

The first and second upper sub-electrodes may each include a plurality of layers. The second upper sub-electrode may include a top layer only.

In the piezoelectric actuator, the first and second sputtering rates are those determined with argon. Argon is an inert gas. Therefore, it hardly occurs that argon combines with the second upper sub-electrode to adversely affect properties of the second upper sub-electrode. Argon has an atomic weight greater than that of nitrogen or another inert gas and therefore has a high sputtering rate. Thus, the use of argon is effective in reducing the time taken to partly remove the protective film and is effective in reducing manufacturing cost.

In the piezoelectric actuator, the first upper sub-electrode has a first Young's modulus and the second upper sub-electrode has a second Young's modulus less than the first Young's modulus. Since the second Young's modulus of the second upper sub-electrode is greater than the first Young's modulus of the first upper sub-electrode, the inhibitory effect of the upper electrode on the deformation of the piezoelectric body is less as compared to the case where all portions of the upper electrode have the first Young's modulus. This allows the piezoelectric actuator to have small differences in vibrational properties.

In the piezoelectric actuator, the second upper sub-electrode has a portion covered with the protective film and a portion which is uncovered from the protective film and which is thicker than the covered portion. The inhibitory effect of the change in thickness of the upper electrode on the deformation of the piezoelectric body is small. This allows the piezoelectric actuator to have small differences in vibrational properties.

In the piezoelectric actuator, the first upper sub-electrode contains at least one selected from the group consisting of iridium, gold, and platinum and the second upper sub-electrode contains at least one selected from the group consisting of titanium, carbon, beryllium, niobium, and molybdenum. Iridium, gold, and platinum, of which at least one is contained in the first upper sub-electrode and titanium, carbon, beryllium, niobium, and molybdenum, of which at least one is contained in the second upper sub-electrode are electrically conductive and therefore function as electrodes. Iridium, gold, and platinum are less in Young's modulus than titanium, carbon, beryllium, niobium, and molybdenum. Therefore, the piezoelectric actuator has the above advantages.

In the piezoelectric actuator, the second upper sub-electrode has a thickness of 10 nm to 30 nm. Even if the thickness of the protective film is non-uniform and the protective film is non-uniformly etched, the first upper sub-electrode is unlikely to be etched and the thickness of the upper electrode is unlikely to be non-uniform, because the thickness of the second upper sub-electrode is 10 nm or more. Since the thickness of the second upper sub-electrodes is 30 nm or less, the upper electrode can be formed so as to have smaller effects on properties of the first upper sub-electrode.

In the piezoelectric actuator, the protective film contains alumina. Since aluminum, which is impermeable to moisture and has good electrical insulation properties, is used to form the protective film, a piezoelectric element is unlikely to be deteriorated by moisture and the piezoelectric actuator can be manufactured so as to have small differences in vibrational properties.

A second aspect of the present invention provides a liquid-ejecting head that includes a channeled substrate including a pressure-generating chamber communicating with a nozzle opening for ejecting a liquid and also includes the piezoelectric actuator. The piezoelectric actuator overlies the channeled substrate and forms a portion of the pressure-generating chamber.

The liquid-ejecting head has the above advantage.

A third aspect of the present invention provides a liquid-ejecting apparatus including the liquid-ejecting head.

The liquid-ejecting apparatus has the above advantage.

A fourth aspect of the present invention provides a method for manufacturing a piezoelectric actuator. The method includes a lower electrode-forming step of forming a lower electrode above a substrate; a piezoelectric film-forming step of forming a piezoelectric film on the lower electrode; a first upper electrode film-forming step of forming a first upper electrode film having a first sputtering rate on the piezoelectric film; a second upper electrode film-forming step of forming a second upper electrode film which has a second sputtering rate less than the first sputtering rate and which is the uppermost layer on the first upper electrode film; a step of forming a piezoelectric body, a first upper sub-electrode, and a second upper sub-electrode from the piezoelectric film, the first upper electrode film, and the second upper electrode film, respectively; a protective film-forming step of forming a protective film over side surfaces of the piezoelectric body and the second upper sub-electrode; and a sputtering step of removing a portion of the protective film that is disposed on the second upper sub-electrode by sputtering.

Since the second sputtering rate of the second upper electrode film is less than the first sputtering rate of the first lower electrode film, the second upper sub-electrode is more unlikely to be sputtered as compared to the case where the upper electrode includes the first upper sub-electrode only when the protective film, which extends over the second upper sub-electrode, is partly removed by sputtering. This allows the second upper sub-electrode to have a small difference in thickness. Therefore, the inhibitory effect of the upper electrode on the deformation of the piezoelectric body can be reduced and the piezoelectric actuator can be manufactured so as to have small differences in vibrational properties.

In the method, the sputtering uses argon and the first and second sputtering rates are those determined with argon. Argon is an inert gas. Therefore, it hardly occurs that argon combines with the second upper sub-electrode to adversely affect properties of the second upper sub-electrode. Argon has an atomic weight greater than that of nitrogen or another gas and therefore has a high sputtering rate. Therefore, the use of argon is effective in reducing the time taken to partly remove the protective film and the piezoelectric actuator can be manufactured by the method at low cost.

In the method, the first upper sub-electrode has a first Young's modulus and the second upper sub-electrode has a second Young's modulus less than the first Young's modulus. The piezoelectric actuator can be manufactured by the method so as to have the above advantage.

In the method, the first upper sub-electrode contains at least one selected from the group consisting of iridium, gold, and platinum and the second upper sub-electrode contains at least one selected from the group consisting of titanium, carbon, beryllium, niobium, and molybdenum. The piezoelectric actuator can be manufactured by the method so as to have the above advantage.

### BRIEF DESCRIPTION OF THE DRAWINGS

The invention will be described with reference to the accompanying drawings, wherein like numbers reference like elements.

FIG. 1 is a schematic view of an ink jet recording apparatus according to an embodiment of the present invention.

FIG. 2 is an exploded perspective view of an ink jet recording head.

FIG. 3A is a fragmentary plan view of the ink jet recording head shown in FIG. 2.

FIG. 3B is a sectional view of the ink jet recording head taken along the line IIIB-IIIB of FIG. 3A.

FIG. 4 is a schematic fragmentary sectional view of the ink jet recording head taken along the line IV-IV of FIG. 3A.

FIG. 5 is a flowchart of a method for manufacturing the piezoelectric actuator.

FIGS. 6A to 6I are schematic fragmentary sectional views illustrating steps of the piezoelectric actuator-manufacturing method.

### DESCRIPTION OF EXEMPLARY EMBODIMENTS

Embodiments of the present invention will now be described in detail with reference to the accompanying drawings.

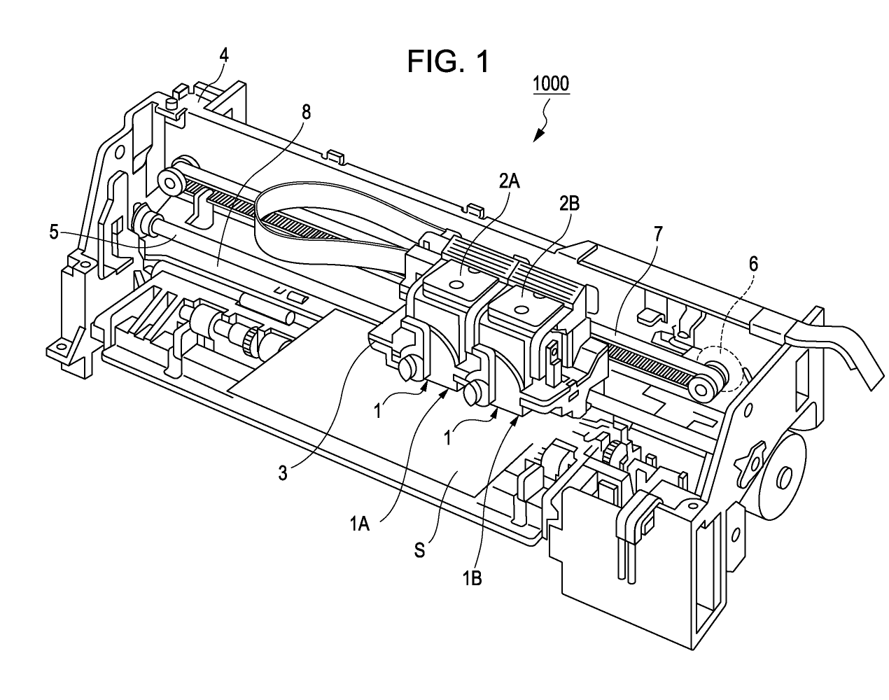

FIG. 1 is a schematic view of an ink jet recording apparatus 1000 according to an embodiment of the present invention. The ink jet recording apparatus 1000 corresponds to a liquid-ejecting apparatus and is a type of equipment that ejects ink which is a liquid toward a recording sheet S which is a recording medium to perform recording.

With reference to FIG. 1, the ink jet recording apparatus 1000 includes a first recording head unit 1A and second recording head unit 1B each including an ink jet recording head 1 which corresponds to a liquid-ejecting head. The first recording head unit 1A and the second recording head unit 1B include a first cartridge 2A and a second cartridge 2B, respectively. The first and second cartridges 2A and 2B are detachable and form an ink supply member.

The ink jet recording heads 1 are located on the sides of the first and second recording head units 1A and 1B that face the recording sheet S.

The first and second recording head units 1A and 1B are mounted on a carriage 3. The carriage 3 is axially slidably engaged with a carriage shaft 5 attached to an apparatus body 4. The first recording head unit 1A and the second recording head unit 1B eject, for example, a black ink composition and a color ink composition, respectively.

The carriage 3, which carries the first and second recording head units 1A and 1B, is moved along the carriage shaft 5 in such a manner that the driving force generated by a driving motor 6 is transmitted to the carriage 3 through a plurality of gears, which are not shown, and a timing belt 7.

The apparatus body 4 is attached to a platen 8 extending along the carriage 3. The platen 8 can be rotated by the driving force generated by a sheet-feeding motor, which is not shown. The recording sheet S, which is a recording medium such as a sheet of paper, is fed by a sheet-feeding roller or the like and is then transported in such a manner that the recording sheet S is wound around the platen 8.

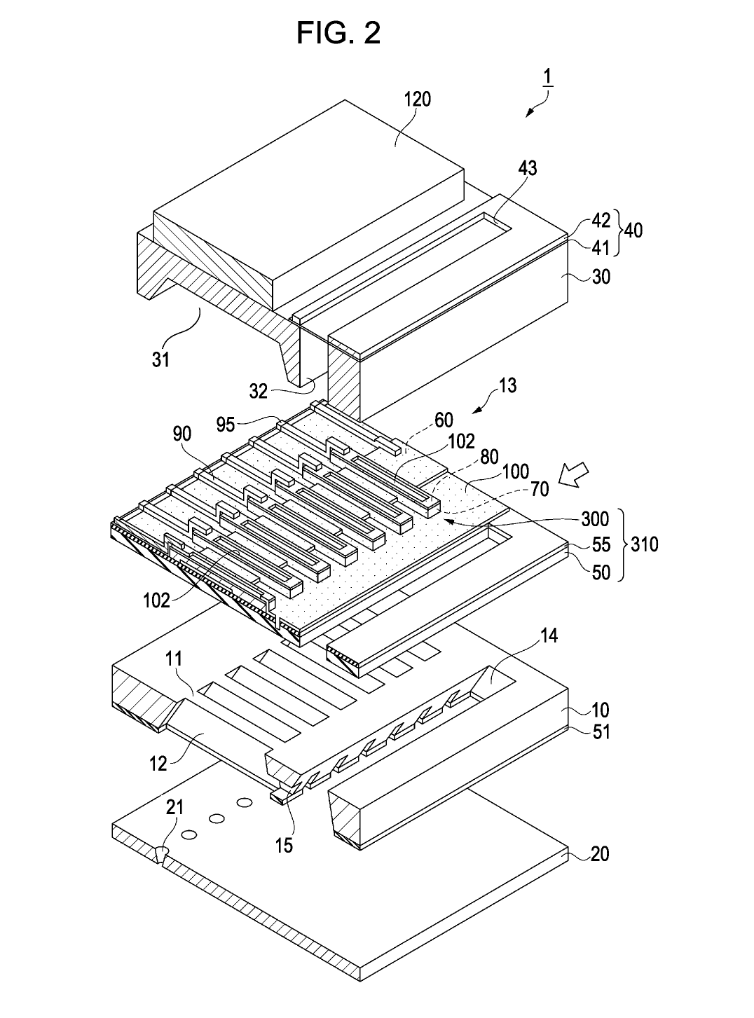

The ink jet recording head 1 has substantially a rectangular parallelepiped shape. FIG. 2 is an exploded perspective view of the ink jet recording head 1 taken along the plane perpendicular to the longitudinal direction of the ink jet recording head 1, that is, the direction indicated by an empty arrow.

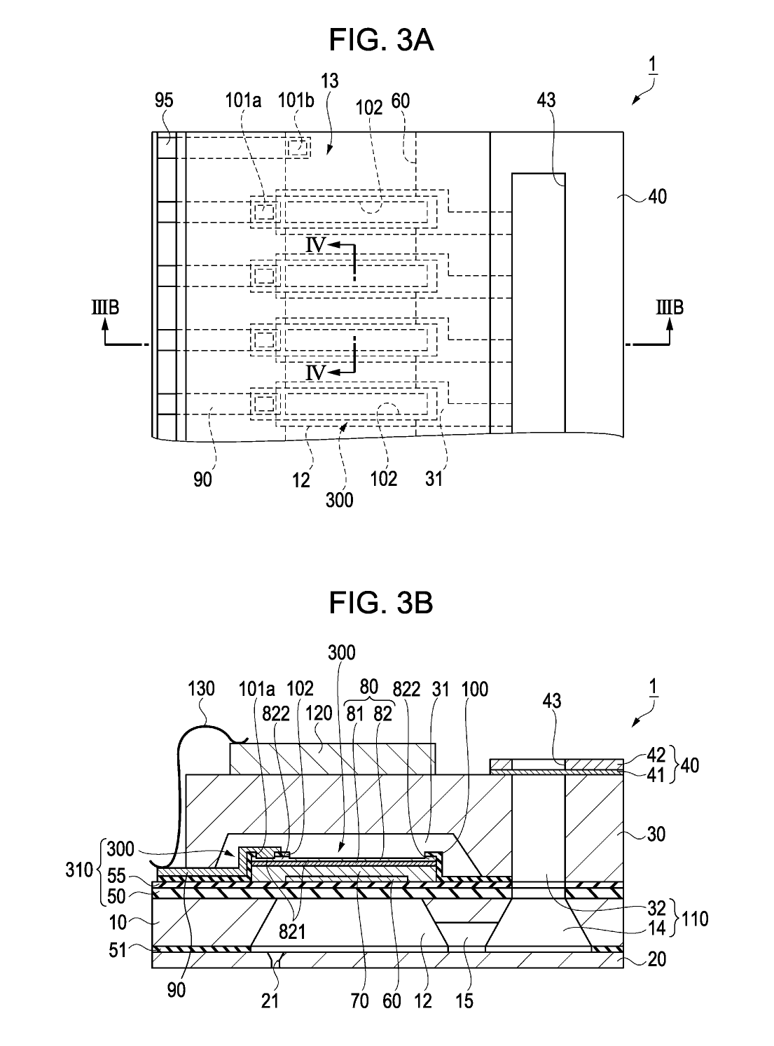

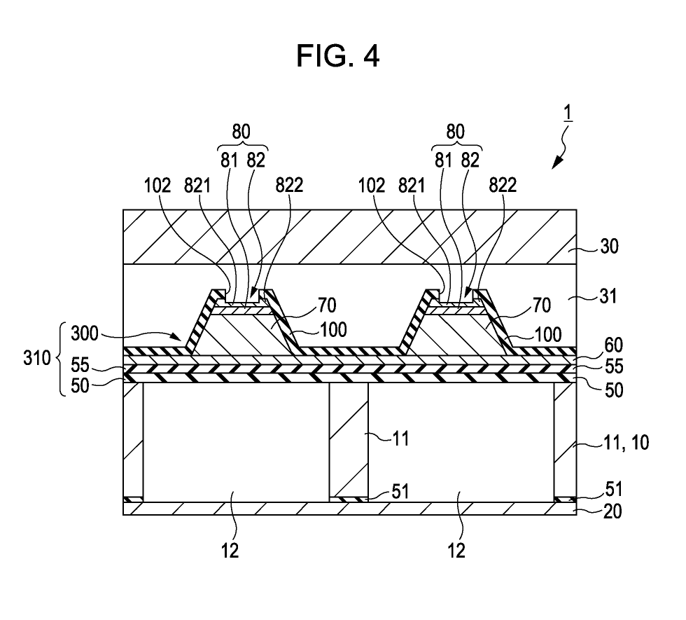

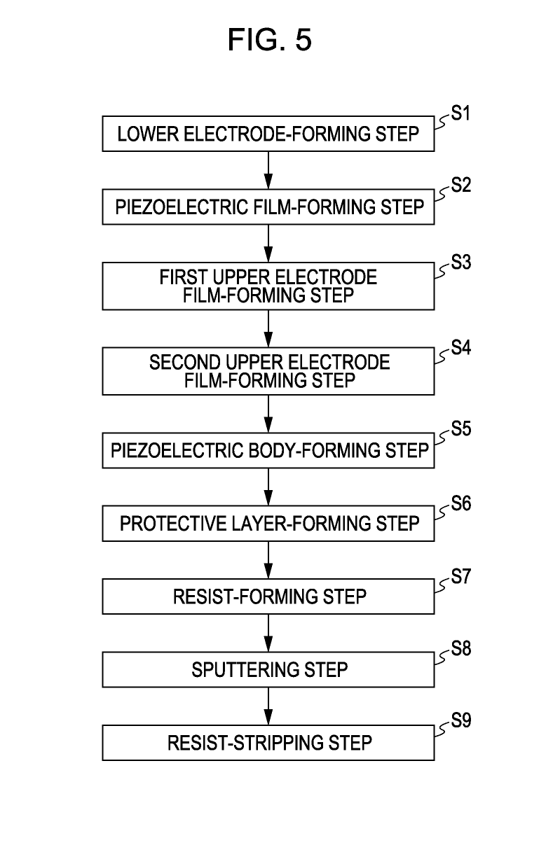

FIG. 3A is a fragmentary plan view of the ink jet recording head 1. FIG. 3B is a sectional view of the ink jet recording head 1 taken along the line IIIB-IIIB of FIG. 3A. FIG. 4 is a schematic fragmentary sectional view of the ink jet recording head 1 taken along the line IV-IV of FIG. 3A.

With reference to FIGS. 2 and 3, the ink jet recording head 1 includes a channeled substrate 10, a nozzle plate 20, a bonding substrate 30, a compliance substrate 40, and a driving integrated circuit (IC) 120.

The channeled substrate 10, the nozzle plate 20, and the bonding substrate 30 are arranged such that the channeled substrate 10 is sandwiched between the nozzle plate 20 and the bonding substrate 30. The compliance substrate 40 is disposed on the bonding substrate 30. The driving IC 120 is disposed on the compliance substrate 40.

The channeled substrate 10 is made of single-crystalline silicon with a (110) orientation. The channeled substrate 10 includes a plurality of pressure-generating chambers 12 formed by anisotropic etching. The pressure-generating chambers 12 are separated from each other by separators 11 and are arranged in the longitudinal direction of the ink jet recording head 1 so as to form a row 13. The pressure-generating chambers 12 are trapezoidal in cross section perpendicular to the longitudinal direction of the ink jet recording head 1. The pressure-generating chambers 12 extend in the width direction of the ink jet recording head 1.

An end portion of the channeled substrate 10 that extends in the width direction of the pressure-generating chambers 12 has an ink supply channel 14. The ink supply channel 14 communicates with the pressure-generating chambers 12 through communicating portions 15. The communicating portions 15 have a width less than that of the pressure-generating chambers 12 and keep the flow resistance of ink, flowing into the pressure-generating chambers 12 through the communicating portions 15, constant.

The nozzle plate 20 has nozzle openings 21 extending therethrough. The nozzle openings 21 communicate with end portions of the pressure-generating chambers 12 located opposite the ink supply channel 14.

The nozzle plate 20 has a thickness of, for example, 0.01 mm to 1.00 mm and is made of, for example, glass ceramic, single-crystalline silicon, stainless steel, or the like.

The channeled substrate 10 and the nozzle plate 20 are fixed to an insulating protective film 51 disposed therebetween with an adhesive, a heat-fusible film, or the like. The insulating protective film 51 is used as a mask for forming the pressure-generating chambers 12 by anisotropic etching.

A surface of the channeled substrate 10 that faces the nozzle plate 20 is overlaid with an elastic film 50 included in a diaphragm. The elastic film 50 includes an oxide layer formed by thermal oxidation. The elastic film 50 has a thickness of, for example, 0.50 μm to 2.00 μm. The elastic film 50, which is disposed on the channeled substrate 10, is overlaid with an insulating film 55 including an oxide layer with a thickness of, for example, about 0.40 μm. The elastic film 50 and the insulating film 55 form the diaphragm.

The elastic film 50 and the insulating film 55, which form the diaphragm, may each include a layer of at least one selected from the group consisting of silicon dioxide, zirconium oxide, and aluminum oxide or may each be a laminate including layers of these oxides.

The following components are arranged on the insulating film 55 in this order to form piezoelectric elements 300: a lower electrode 60 with a thickness of, for example, about 0.20 μm; piezoelectric bodies 70 having a thickness of, for example, about 1.30 μm and a perovskite structure; and upper electrodes 80 with a thickness of, for example, about 0.05 μm. The piezoelectric elements 300 are defined as regions including portions of the lower electrode 60, the piezoelectric bodies 70, and the upper electrodes 80. The diaphragm is vibrated by driving the piezoelectric elements 300. The diaphragm is deformed by the operation of the piezoelectric elements 300, whereby the pressure-generating chambers 12 are changed in volume. A reduction in the volume of each pressure-generating chamber 12 filled with ink increases the pressure in the pressure-generating chamber 12. This allows the ink to be ejected from the nozzle openings 21, which are arranged in the nozzle plate 20.

The lower electrode 60 is disposed in a region which faces the pressure-generating chambers 12 and which extends in the longitudinal direction of the pressure-generating chambers 12. The lower electrode 60 continuously extends over regions corresponding to the pressure-generating chambers 12. The lower electrode 60 extends out of the row 13 of the pressure-generating chambers 12.

A material for forming the lower electrode 60 is not particularly limited and may be a metal such as nickel, iridium, or platinum; a conducting oxide such as iridium oxide; a strontium-ruthenium composite oxide; or a lanthanum-nickel composite oxide.

Portions of the lower electrode 60 are paired with the upper electrodes 80 such that the piezoelectric bodies 70 are sandwiched therebetween. The lower electrode 60 can function as a common electrode for the piezoelectric elements 300. The lower electrode 60 is electrically connected to an external circuit, which is not shown.

The piezoelectric bodies 70 are preferably made of a perovskite-type oxide represented by the formula ABO₃. Examples of the perovskite-type oxide include lead zirconate titanate (Pb(Zr, Ti)O₃) (hereinafter simply referred to as PZT), lead zirconate titanate niobate (Pb(Zr, Ti, Nb)O₃) (hereinafter simply referred to as PZTN® in some cases), barium titanate (BaTiO₃), and potassium sodium niobate ((K, Na)NbO₃).

The piezoelectric bodies 70 can be stretchably deformed to generate mechanical force when electric fields are applied to the piezoelectric bodies 70 by the lower electrode 60 and the upper electrodes 80. The piezoelectric bodies 70 are more preferably made of PZT or PZTN® because PZT and PZTN® have particularly good piezoelectric properties.

The upper electrodes 80 include first upper sub-electrodes 81 and second upper sub-electrodes 82 that are the uppermost layers. The first upper sub-electrodes 81 are disposed on the piezoelectric bodies 70. The second upper sub-electrodes 82 are disposed on the first upper sub-electrodes 81.

The second upper sub-electrodes 82 include thin portions 821 and thick portions 822 thicker than the thin portions 821.

The first upper sub-electrodes 81 preferably have a thickness of, for example, 20 nm to 40 nm and preferably contains at least one selected from the group consisting of iridium, gold, and platinum.

The second upper sub-electrodes 82 preferably have a thickness of, for example, 10 nm to 30 nm. The first upper sub-electrodes 81 have a first sputtering rate and a first Young's modulus. A material that has a second sputtering rate less than the first sputtering rate is preferably selected to form the second upper sub-electrodes 82, the first and second sputtering rates being determined with argon. Alternatively, a material that has a second Young's modulus less than the first Young's modulus is preferably selected to form the second upper sub-electrodes 82. Such a material is at least one selected from the group consisting of titanium, carbon, beryllium, niobium, and molybdenum.

The sputtering rate of iridium is 1.01, that of platinum is 1.40, that of titanium is 0.51, and that of carbon is 0.12 as sputtered with argon at 0.5 keV to 10 keV (see Japan Society of Applied Physics, Applied Physics Data Book, 1994, p. 308).

The Young's modulus of iridium is about 529×10⁹ N/m², that of platinum is about 152×10⁹ N/m², and that of titanium is about 116×10⁹ N/m².

In general, one of the electrodes of each piezoelectric element 300 is used as a common electrode and the other one and a corresponding one of the piezoelectric bodies 70 are formed by patterning so as to correspond to a corresponding one of the pressure-generating chambers 12. The following portion is hereinafter referred to as a piezoelectric active portion: each portion which includes one of the electrodes and a corresponding one of the piezoelectric bodies 70 and which generates piezoelectric stress when a voltage is applied between the electrodes.

In this example, the lower electrode 60 is used as a common electrode for the piezoelectric elements 300 and the upper electrodes 80 are used as individual electrodes for the piezoelectric elements 300. The lower electrode 60 and the upper electrodes 80 may be reversed in accordance with driving circuits or wiring. In both cases, the pressure-generating chambers 12 each have the piezoelectric active portion. The following region is hereinafter referred to as a piezoelectric actuator 310: a region including the piezoelectric elements 300; the elastic film 50, which is deformed by driving the piezoelectric elements 300; the insulating film 55; and a portion of the channeled substrate 10.

With reference to FIGS. 2, 3, and 4, the piezoelectric elements 300 are covered with a protective film 100 which corresponds to an insulating member.

A material for forming the protective film 100 is not particularly limited and may be an inorganic material such as aluminum oxide (AlOₓ) or tantalum oxide (TaOₓ).

With reference to FIGS. 2 and 3, the upper electrodes 80, which are included in the piezoelectric elements 300, are connected to upper electrode lead electrodes 90 made of, for example, gold (Au) through first connection holes 101a arranged in the protective film 100.

A second connection hole 101b for connecting the lower electrode 60 to a lower lead electrode 95 is disposed outside the row 13 of the piezoelectric elements 300.

The protective film 100, which extends over the upper electrodes 80, has holes 102, formed by partly removing the protective film 100, each having a rectangular opening. The second upper sub-electrodes 82 are partly exposed through the holes 102. Therefore, patterned regions of layers forming the piezoelectric elements 300 are covered with the protective film 100 except the first and second connection holes 101a and 101b and the holes 102.

The bonding substrate 30, on which the driving IC 120 for driving the bonding substrate 30 is mounted, is fixed on the channeled substrate 10, which underlies the piezoelectric elements 300.

The bonding substrate 30 includes a piezoelectric element-holding portion 31 that can seal a space which is disposed in a region facing the piezoelectric elements 300 which is secured so as not to inhibit the motion of the bonding substrate 30. The piezoelectric element-holding portion 31 is located so as to correspond to the row 13 of the pressure-generating chambers 12.

In this embodiment, the single piezoelectric element-holding portion 31 is located at a position corresponding to the row 13 of the pressure-generating chambers 12. Instead, separate piezoelectric element-holding portions may be each arranged above a corresponding one of the piezoelectric elements 300. Examples of a material for forming the bonding substrate 30 include glass, ceramic materials, metals, and resins. The bonding substrate 30 is preferably made of a material having substantially the same thermal expansion coefficient as that of the channeled substrate 10. In this embodiment, the bonding substrate 30 as well as the channeled substrate 10 is made of single-crystalline silicon.

The bonding substrate 30 includes a reservoir portion 32 located at a position corresponding to the ink supply channel 14, which is disposed in the channeled substrate 10. In this embodiment, the reservoir portion 32 extends through the bonding substrate 30 in the thickness direction thereof and also extends along the row 13 of the pressure-generating chambers 12. The reservoir portion 32 communicates with the ink supply channel 14. The reservoir portion 32 and the ink supply channel 14 form a reservoir 110 serving as an ink chamber common to the pressure-generating chambers 12.

The bonding substrate 30 underlies a wiring pattern, which is not shown. The wiring pattern is connected to an external lead such that a driving signal is supplied to the wiring pattern. The driving IC 120, which is a semiconductor integrated circuit (IC) for driving the piezoelectric elements 300, is mounted on the wiring pattern.

Examples of the driving signal include driving signals, such as driving power-supply signals, for driving the driving IC 120 and control signals such as serial signals (SIs). The wiring pattern includes a plurality of lines supplied with signals.

The upper electrode lead electrodes 90 are each connected to the vicinity of a corresponding one of ends of the upper electrodes 80. The upper electrode lead electrodes 90 extend from the piezoelectric elements 300 and are electrically connected to the driving IC 120 through connection lines 130 including conducting wires such as bonding wires. The lower lead electrode 95 is electrically connected to the driving IC 120 through a connection line, which is not shown.

The compliance substrate 40 is fixed on the bonding substrate 30 and includes a sealing film 41 and a fixed plate 42. The sealing film 41 is made of a flexible material, such as polyphenylene sulfide (PPS), having low rigidity and has a thickness of, for example, 6 μm. A surface of the reservoir portion 32 is sealed with the sealing film 41. The fixed plate 42 is made of a hard material such as a metal material including stainless steel (SUS) and has a thickness of, for example, 30 μm. The fixed plate 42 has an opening 43, formed by completely removing a portion of the fixed plate 42 in the thickness direction thereof, facing the reservoir 110; hence, a surface of the reservoir 110 is sealed with the sealing film 41, which is flexible.

The ink jet recording head 1 is supplied with ink from an external ink supply unit, which is not shown, such that an internal portion extending from the reservoir 110 to the nozzle openings 21 is filled with the ink. The elastic film 50, the insulating film 55, the lower electrode 60, and the upper electrodes 80 are then deformed in such a manner that driving voltages are applied between the lower electrode 60 and the upper electrodes 80, which correspond to the pressure-generating chambers 12, in accordance with a driving signal transmitted from the driving IC 120, whereby the pressure in each pressure-generating chamber 12 is increased and therefore droplets of the ink are ejected from the nozzle openings 21.

A method for manufacturing the piezoelectric actuator 310 is described below in detail.

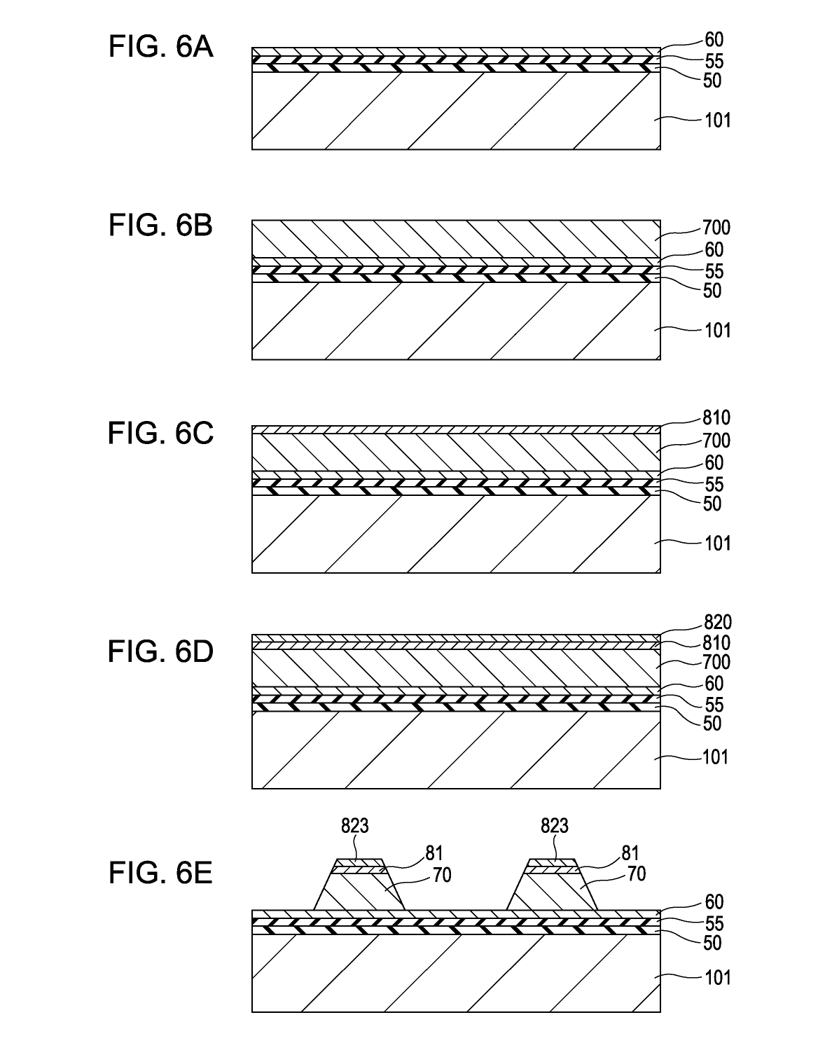

FIG. 5 is a flowchart of a procedure, included in the piezoelectric actuator 310-manufacturing method, for preparing the piezoelectric elements 300.

The piezoelectric actuator 310-manufacturing method includes Step 1 (S1) corresponding to a lower electrode-forming step, Step 2 (S2) corresponding to a piezoelectric film-forming step, Step 3 (S3) corresponding to a first upper electrode film-forming step, Step 4 (S4) corresponding to a second upper electrode film-forming step, Step 5 (S5) corresponding to a piezoelectric body-forming step, Step 6 (S6) corresponding to a protective film-forming step, Step 7 (S7) corresponding to s a resist-forming step, Step 8 (S8) corresponding to a sputtering step, and Step 9 (S9) corresponding to a resist-removing step.

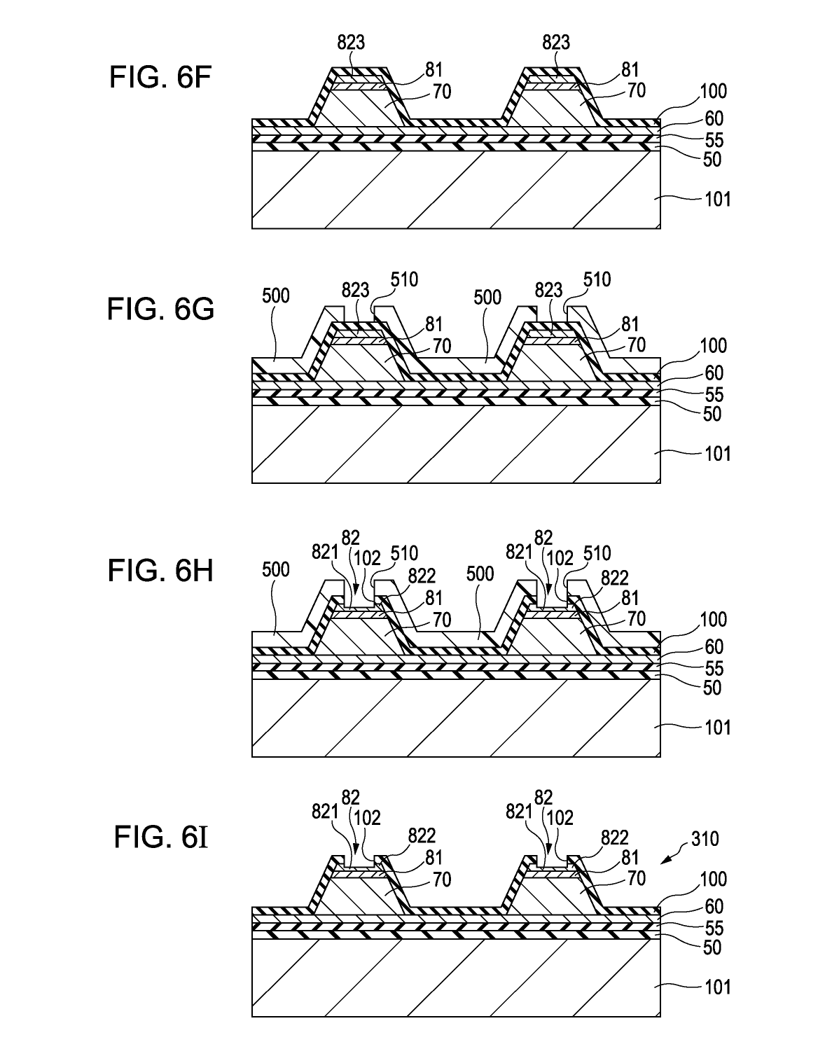

FIGS. 6A to 6I are schematic fragmentary sectional views illustrating the piezoelectric element 300-preparing procedure, which is included in the piezoelectric actuator 310-manufacturing method. The schematic fragmentary sectional views are taken along the line VI-VI of FIG. 3A.

In particular, FIG. 6A illustrates the lower electrode-forming step (S1), FIG. 6B illustrates the piezoelectric film-forming step (S2), FIG. 6C illustrates the first upper electrode film-forming step (S3), FIG. 6D illustrates the second upper electrode film-forming step (S4), FIG. 6E illustrates the piezoelectric body-forming step (S5), FIG. 6F illustrates the protective film-forming step (S6), FIG. 6G illustrates the resist-forming step (S7), FIG. 6H illustrates the sputtering step (S8), and FIG. 6I illustrates the resist-removing step (S9).

In the lower electrode-forming step (S1), as shown in FIG. 6A, the lower electrode 60 is formed above an channel-forming substrate 101. In particular, the lower electrode 60 is formed on the insulating film 55. The elastic film 50 and the insulating film 55 are arranged on the channel-forming substrate 101 in that order.

The elastic film 50 and the insulating film 55, which are members of the diaphragm, can be formed by a sputtering process, a vacuum vapor deposition process, or a chemical vapor deposition (CVD) process, or another process.

The lower electrode 60 can be formed in such a manner that a conducting film is formed by a sputtering process, a vacuum vapor deposition process, a CVD process, or another process and is then patterned by photolithography or the like. Alternatively, the lower electrode 60 may be formed by a printing process requiring no patterning.

The lower electrode 60 may include a single layer of the above-mentioned material or stacked layers of a plurality of materials.

In the piezoelectric film-forming step (S2), as shown in FIG. 6B, a piezoelectric film 700 is formed on the lower electrode 60.

The piezoelectric film 700 can be formed by a sol-gel process, a CVD process, or another process. For the sol-gel process, a series of operations such as the application of a source solutions preheating, and crystallization annealing may be repeated several times such that the piezoelectric film 700 has a predetermined thickness.

When the piezoelectric film 700 is made of PZT, the piezoelectric film 700 can be formed by a spin coating process, a printing process, or another process using a sol-gel solution containing lead, zirconium, and titanium.

In the first upper electrode film-forming step (S3), as shown in FIG. 6C, a first upper electrode film 810 is formed on the piezoelectric film 700 using the material for forming the first upper sub-electrodes 81. The first upper electrode film 810 can be formed by a sputtering process, a vacuum vapor deposition process, or another process.

In the second upper electrode film-forming step (S4), as shown in FIG. 6D, a second upper electrode film 820 is formed on the first lower electrode film 810 using the material for forming the second upper sub-electrodes 82. The first lower electrode film 810 has a first sputtering rate and the second upper electrode film 820 has a second sputtering rate less than the first sputtering rate as sputtered with argon.

The second upper electrode film 820 as well as the first lower electrode film 810 can be formed by a sputtering process, a vacuum vapor deposition process, or another process.

In the piezoelectric body-forming step (S5), as shown in FIG. 6E, the first lower electrode film 810, the second upper electrode film 820, and the piezoelectric film 700 are dry- or wet-etched in such a manner that the second upper electrode film 820 is masked, whereby the piezoelectric bodies 70, which are shown in FIGS. 2 and 3, are formed so as to each correspond to a corresponding one of the pressure-generating chambers 12. In this step, the first lower electrode film 810 and the second upper electrode film 820 are etched, whereby the first upper sub-electrodes 81 and second upper sub-electrode precursors 823 are formed on the piezoelectric bodies 70 in that order. For example, a piezoelectric material such as lead zirconate titanate (PZT) can be wet-etched with a combination of various acids. For example, the following solution can be used: an etching solution containing 75% of water and 25% of a mixture of ethylenediaminetetraacetic acid (EDTA), hydrochloric acid, acetic acid, nitric acid, ammonium chloride, and a buffered oxide etching solution.

The first lower electrode film 810, the second upper electrode film 820, and the piezoelectric film 700 can be patterned by a process such as photolithography using a mask or the like. In this step, photolithography may be performed several times. A process such as dry etching can be used in this step.

In the protective film-forming step (S6), as shown in FIG. 6F, the protective film 100 is formed over side surfaces of the piezoelectric bodies 70, the lower electrode 60, the first upper sub-electrodes 81, and the second upper sub-electrode precursors 823. The protective film 100 can be formed by, for example, a CVD process. Conditions, such as temperatures and gas flow rates, for forming the protective film 100 are appropriately controlled, whereby the protective film 100 can be readily formed so as to have desired properties such as density and Young's modulus.

In the resist-forming step (S7), as shown in FIG. 6G, a resist 500 is formed over the protective film 100 and is then partly removed by wet etching using an organic acid or the like or by dry etching using oxygen plasma for asking, whereby apertures 510 are formed in the resist 500. The apertures 510 are located at positions corresponding to the holes 102, which are disposed in the protective film 100.

In the sputtering step (S8), as shown in FIG. 6H, portions of the protective film 100 that are disposed on the second upper sub-electrode precursors 823 are etched off in such a manner that the protective film 100 is sputtered through the apertures 510 using argon. In this step, the second upper sub-electrode precursors 823 are partly sputtered because of the thickness variation of the protective film 100 and a fluctuation in sputtering and therefore the thin portions 821 are formed, whereby the second upper sub-electrodes 82, which include the thin portions 821 and the thick portions 822, are formed. This allows the first upper sub-electrodes 81 and the second upper sub-electrodes 82 to form the upper electrodes 80.

The sputtering step can be performed by ion milling using an ion beam.

In the resist-removing step (S9), as shown in FIG. 6I, the resist 500 subjected to sputtering is stripped off, whereby the piezoelectric actuator 310 is obtained.

After these steps, the channel-forming substrate 101 is etched such that the pressure-generating chambers 12 are formed in the channel-forming substrate 101 so as to extend to the elastic film 50, whereby the piezoelectric active portions are formed in the pressure-generating chambers 12 and therefore the piezoelectric actuator 310 can be operated.

Components of the ink jet recording head 1, which include the piezoelectric elements 300 and the piezoelectric actuator 310, are formed on a wafer and are then separated from each other, whereby the ink jet recording head 1 is obtained.

According to the above embodiment, advantages below can be obtained.

(1) Since the second sputtering rate of the second upper sub-electrodes 82 is less than the first sputtering rate of the first upper sub-electrodes 81, the second upper sub-electrodes 82 are more resistant to sputtering when the portions of the protective film 100 that are disposed on the second upper sub-electrodes 82 are removed by sputtering as compared to the case where the upper electrodes 80 include the first upper sub-electrodes 81 only; hence, the difference in thickness between the second upper sub-electrodes 82 can be reduced. Therefore, the inhibitory effect of the upper electrodes 80 on the deformation of the piezoelectric bodies 70 can be reduced. This allows the piezoelectric actuator 310 to have small differences in vibrational properties.

(2) Argon is an inert gas. Therefore, it hardly occurs that argon combines with the second upper sub-electrodes 82 to adversely affect properties of the second upper sub-electrodes 82. Argon has an atomic weight greater than that of nitrogen or another inert gas and therefore has a high sputtering rate. Thus, the use of argon is effective in reducing the time taken to partly remove the protective film 100 and is effective in reducing manufacturing cost.

(3) Since the second Young's modulus of the second upper sub-electrodes 82 is greater than the first Young's modulus of the first upper sub-electrodes 81, the inhibitory effect of the upper electrodes 80 on the deformation of the piezoelectric bodies 70 can be reduced as compared with the case where all portions of the upper electrodes 80 have the first Young's modulus. This allows the piezoelectric actuator 310 to have small differences in vibrational properties.

(4) The inhibitory effect of the change in thickness of the upper electrodes 80 on the deformation of the piezoelectric bodies 70 can be reduced. This allows the piezoelectric actuator 310 to have small differences in vibrational properties.

(5) The following elements are electrically conductive and therefore function as electrodes: iridium, gold, and platinum, of which at least one is contained in the first upper sub-electrodes 81 and titanium, carbon, beryllium, niobium, and molybdenum, of which at least one is contained in the second upper sub-electrodes 82. Iridium, gold, and platinum are less in Young's modulus than titanium, carbon, beryllium, niobium, and molybdenum. Therefore, the piezoelectric actuator 310 has the above advantages.

(6) Even if the protective film 100 is non-uniform in thickness and is non-uniformly etched, the first upper sub-electrodes 81 are unlikely to be etched and therefore there is substantially no difference in thickness between the upper electrodes 80 because the second upper sub-electrodes 82 have a thickness of 10 nm or more. Since the second upper sub-electrodes 82 have a thickness of 30 nm or less, the upper electrodes 80 can be formed so as to have smaller effects on properties of the first upper sub-electrodes 81.

(7) Since aluminum, which is impermeable to moisture and has good electrical insulation properties, is used to form the protective film 100, the piezoelectric elements 300 are unlikely to be deteriorated by moisture and the piezoelectric actuator 310 can be manufactured so as to have small differences in vibrational properties.

(8) The ink jet recording head 1 and the ink jet recording apparatus 1000 can be manufactured so as to have the above advantages. Since the piezoelectric actuator 310 has small differences in vibrational properties, the ink jet recording head 1 and the ink jet recording apparatus 1000 are capable of forming an image which has small differences in width between lines and which is prevented from being deteriorated in quality.

(9) Since the second sputtering rate of the second upper electrode film 820 is less than the first sputtering rate of the first lower electrode film 810, the second upper sub-electrodes 82 are more unlikely to be sputtered as compared to the case where the upper electrodes 80 include the first upper sub-electrodes 81 only when the protective film 100, which extends over the second upper sub-electrodes 82, is partly removed by sputtering. This allows the second upper sub-electrodes 82 to have small differences in thickness. Therefore, the inhibitory effect of the upper electrodes 80 on the deformation of the piezoelectric bodies 70 can be reduced and the piezoelectric actuator 310 can be manufactured so as to have small differences in vibrational properties.

(10) Argon is an inert gas. Therefore, it hardly occurs that argon combines with the second upper sub-electrodes 82 to adversely affect properties of the second upper sub-electrodes 82. Argon has an atomic weight greater than that of nitrogen or another gas and therefore has a high sputtering rate. Therefore, the use of argon is effective in reducing the time taken to partly remove the protective film 100 and the piezoelectric actuator 310 can be manufactured by the method at low cost.

(11) Another method for manufacturing a piezoelectric actuator having the above advantages can be obtained.

Various modifications other than the above embodiment can be made.

The shape of the holes 102 is not limited to the above rectangular shape. The holes 102 may have, for example, a rectangular shape with short arches or substantially an elliptical shape.

The first lower electrode film 810 and the second upper electrode film 820 may be directly formed over the etched piezoelectric bodies 70 and then processed into the first upper sub-electrodes 81 and the second upper sub-electrodes precursors 823, respectively, which are disposed on the piezoelectric bodies 70.

A substrate for forming the piezoelectric actuator 310 is not limited to the channeled substrate 10. For example, a semiconductor substrate, a resin substrate, or another substrate can be arbitrarily used to form the piezoelectric actuator 310 depending on applications thereof.

The diaphragm may include, for example, stacked layers made of a metal such as stainless steel. The lower electrode 60 may functions as a diaphragm.

In the above embodiment, the piezoelectric elements 300 are arranged in the piezoelectric element-holding portion 31 of the bonding substrate 30. The piezoelectric elements 300 may be exposed. In this case, the lower surfaces of the piezoelectric elements 300 and those of the upper electrode lead electrodes 90 are covered with the protective film 100, which is made of an inorganic insulating material and therefore the piezoelectric bodies 70 can be securely prevented from being damaged by water (moisture).

In the above embodiment, the liquid-ejecting head is described using the ink jet recording head 1 as an example. The present invention is directed to a wide range of liquid-ejecting heads and is applicable to liquid-ejecting heads for ejecting liquids other than ink. Examples of the liquid-ejecting head include various recording heads for use in image-recording apparatuses such as printers; colorant-ejecting heads used to manufacture color filters for liquid crystal displays; electrode material-ejecting heads used to form electrodes for organic electroluminescent (EL) displays, field emission displays (FEDs), and other displays; and bio-organic substance-ejecting heads used to manufacture bio-chips.

What is claimed is:

1. A piezoelectric actuator comprising:
a substrate;
a diaphragm overlying the substrate;
a lower electrode overlying the diaphragm;
a piezoelectric body overlying the lower electrode;
an upper electrode that includes a first upper sub-electrode which overlies the piezoelectric body and which has a first sputtering rate and also includes a second upper sub-electrode which overlies the first upper sub-electrode, which has a second sputtering rate less than the first sputtering rate, and which is the uppermost layer; and
a protective film extending over side surfaces of the piezoelectric body and the second upper sub-electrode, a portion of the protective film that overlies the second upper sub-electrode being removed by sputtering.

2. The piezoelectric actuator according to claim 1, wherein the first and second sputtering rates are those determined with argon.

3. The piezoelectric actuator according to claim 1, wherein the first upper sub-electrode has a first Young's modulus and the second upper sub-electrode has a second Young's modulus less than the first Young's modulus.

4. The piezoelectric actuator according to claim 1, wherein the second upper sub-electrode has a portion covered with the protective film and a portion which is uncovered from the protective film and which is thicker than the covered portion.

5. The piezoelectric actuator according to claim 1, wherein the first upper sub-electrode contains at least one selected from the group consisting of iridium, gold, and platinum and the second upper sub-electrode contains at least one selected from the group consisting of titanium, carbon, beryllium, niobium, and molybdenum.

6. The piezoelectric actuator according to claim 1, wherein the second upper sub-electrode has a thickness of 10 nm to 30 nm.

7. The piezoelectric actuator according to claim 1, wherein the protective film contains alumina.

8. A liquid-ejecting head comprising:
a channeled substrate including a pressure-generating chamber communicating with a nozzle opening for ejecting a liquid; and
a piezoelectric actuator including:
a substrate;
a diaphragm overlying the substrate;
a lower electrode overlying the diaphragm;
a piezoelectric body overlying the lower electrode;
an upper electrode that includes a first upper sub-electrode which overlies the piezoelectric body and which has a first sputtering rate and also includes a second upper sub-electrode which overlies the first upper sub-electrode, which has a second sputtering rate less than the first sputtering rate, and which is the uppermost layer; and
a protective film extending over side surfaces of the piezoelectric body and the second upper sub-electrode, a portion of the protective film that overlies the second upper sub-electrode being removed by sputtering,
wherein the piezoelectric actuator overlies the channeled substrate and forms a portion of the pressure-generating chamber.

9. The liquid-ejecting head according to claim 8, wherein the first and second sputtering rates are those determined with argon.

10. The liquid-ejecting head according to claim 8, wherein the first upper sub-electrode has a first Young's modulus and the second upper sub-electrode has a second Young's modulus less than the first Young's modulus.

11. The liquid-ejecting head according to claim 8, wherein the second upper sub-electrode has a portion covered with the protective film and a portion which is uncovered from the protective film and which is thicker than the covered portion.

12. The liquid-ejecting head according to claim 8, wherein the first upper sub-electrode contains at least one selected from the group consisting of iridium, gold, and platinum and the second upper sub-electrode contains at least one selected from the group consisting of titanium, carbon, beryllium, niobium, and molybdenum.

13. The liquid-ejecting head according to claim 8, wherein the second upper sub-electrode has a thickness of 10 nm to 30 nm.

14. The liquid-ejecting head according to claim 8, wherein the protective film contains alumina.

15. A liquid-ejecting apparatus comprising the liquid-ejecting head according to claim 8.

16. A method for manufacturing a piezoelectric actuator, comprising:
forming a lower electrode above a substrate;
forming a piezoelectric film on the lower electrode;
forming a first upper electrode film having a first sputtering rate on the piezoelectric film;
forming a second upper electrode film which has a second sputtering rate less than the first sputtering rate and which is the uppermost layer on the first upper electrode film;
forming a piezoelectric body, a first upper sub-electrode, and a second upper sub-electrode from the piezoelectric film, the first upper electrode film, and the second upper electrode film, respectively;
forming a protective film over side surfaces of the piezoelectric body and the second upper sub-electrode; and
removing a portion of the protective film that is disposed on the second upper sub-electrode by sputtering.

17. The method for manufacturing a piezoelectric actuator according to claim 16, wherein the sputtering uses argon and the first and second sputtering rates are those determined with argon.

18. The method for manufacturing a piezoelectric actuator according to claim 16, wherein the first upper sub-electrode has a first Young's modulus and the second upper sub-electrode has a second Young's modulus less than the first Young's modulus.

19. The method for manufacturing a piezoelectric actuator according to claim 16, wherein the first upper sub-electrode contains at least one selected from the group consisting of iridium, gold, and platinum and the second upper sub-electrode contains at least one selected from the group consisting of titanium, carbon, beryllium, niobium, and molybdenum.
